(19) United States
(12) Patent Application Publication
(10) Pub. No.: US 2010/0244731 A1
(43) Pub. Date: Sep. 30, 2010

(54) WHITE LIGHT EMITTING DIODE, WHITE LIGHT EMITTING APPARATUS, AND LINEAR ILLUMINATOR USING THE SAME

(75) Inventors: Takahiro Kaihotsu, Kanagawa (JP); Shozo Asai, Saitama (JP)

Correspondence Address: FITZPATRICK CELLA HARPER & SCINTO, 1290 Avenue of the Americas, NEW YORK, NY, 10104-3800, US

(73) Assignee: CANON COMPONENTS, INC., Saitama (JP)

(21) Appl. No.: 12/447,487

(22) PCT Filed: Aug. 1, 2008
(86) PCT No.: PCT/JP2008/063839

§ 371 Date: Apr. 28, 2009

(30) Foreign Application Priority Data
Feb. 13, 2008 (JP) 2008-031470

(51) Int. Cl. H05B 37/02; H01L 33/44; H01L 33/50; F21V 8/00

(52) U.S. Cl. 315/294; 257/91; 362/555; 257/98; 257/E33.061

(57) ABSTRACT

A white light emitting apparatus (20) is provided with a first white light emitting diode (11) that emits yellowish white and a second white light emitting diode (12) that emits bluish white in the same direction of the light emitted from the first white light emitting diode (11). The white light emitting apparatus (20) is further provided with a current control circuit that controls drive currents of the first and second white light emitting diodes (11, 12).

### TECHNICAL FIELD

The present invention relate to a white light emitting diode, a white light emitting apparatus, and a linear illuminator to achieve emission of a light having a high degree of whiteness.

### BACKGROUND ART

A white light emitting diode which includes a blue LED chip and a fluorescent layer that covers the blue LED chip and contains a YAG fluorescent substance for converting blue and other color of a light into yellow has been proposed. The white light emitting diode has an advantage that the thickness and weight thereof are reduced.

FIG. 14 shows one example of a structure of a conventional white light emitting diode 101. Now, the operation for emitting a light of the white light emitting diode 101 will be explained below. A blue LED chip 102 powered by a wiring 105 emits a blue light, which passes through a fluorescent layer 103 that is configured with transparent resin with YAG fluorescent particles dispersed therein. In the passing, a part of blue light interacts with the YAG fluorescent particles, which causes wavelength conversion. As a result, a yellow light is emitted. Other part of the blue light does not interact with the YAG fluorescent particles, and is emitted as it is. Therefore, the yellow light and the blue light are emitted as a light of color mixture, resulting in an emission of a white light. In this way, the white light emitting diode 101 functions as a source of white light. The white light emitting diode 101 is mounted to a printed circuit board 106, and is electrically controlled to operate to emit a light. The blue light LED chip 102 and the fluorescent layer 103 are housed in a package 104.

However, the white light emitting diode 101 is known for the variation in the outputs and wavelengths of the blue LED chip 101. The fluorescent layer 103 often has variation in its thickness, non-uniformity of dispersed fluorescent particles, variation in excitation wavelengths by the fluorescent particles, and the like. These factors are complexly intertwined with each other, as the result of that the distribution of resulting emission spectrum is sometimes biased, and the color of the emitted light is deviated from the white point on a chromaticity diagram. That means the above factors may cause manufacture defect of the white light emitting diode 101.

The quality of a white light emitting diode is often checked by a selector, but the selector does not always provide adequate selection. So, Patent Document 1 discloses a technology for changing an average current value and/or a duty ratio of a pulse current which is used to drive a white light emitting diode to cause the color of the emitted light to be adjusted to the white point on a chromaticity diagram.

However, there is a limit in the range available for the adjustment of the average current value and/or the duty ratio. Thus, the use of a white light emitting diode that achieves high color purity of white is necessary to control the adjustment to the white point. That means that a white light emitting diode having a color temperature within a range of “X=0.315 to 0.345, Y=0.295 to 0.365” is inevitably selected at the initial stage so as to adjust the color of an emitted light to the white point on a chromaticity diagram (X, Y=0.33, 0.33) in the prior art. This narrows the range of white light emitting diodes that can be used.

Patent Document 2 discloses a technology for manufacturing a white light emitting diode, in which a peak wavelength is measured for each blue light LED chip and a thickness of a fluorescent layer provided to the blue light LED chip is determined based on the measured result. In addition, Patent Document 3 discloses a technology for manufacturing a white light emitting diode, in which the hue of an emitted light from a blue light LED chip is measured in front of a fluorescent layer, and based on the measured result, the intensity balance of the resulting color mixture, the wavelength of a light emitted from the blue light LED chip, the type of the fluorescent layer, and the like are changed.

These technologies described in Patent Document 2 and 3 allowed the reduction of variations in chromaticity of an emitted light from a white light emitting diode. However, in these technologies, a measurement of emission spectrum or the like for every blue light LED chip or every part finished product of a white light emitting diode which is a combination of a blue light LED chip and a fluorescent layer, and then an adjustment of the property of the fluorescent layer depending on the measured result are necessary. As a result, careful control is performed for each white light emitting diode, and so the above technologies cannot be regarded as proper technologies for mass production.

In the above context, Patent Document 4 and the other documents also disclose linear illuminators for linearly illuminating manuscript and the like with a light guided by a light guide member which uses an LED as a light source.

[Patent Document 1] Japanese Laid-Open Patent Publication No. 2002-134284

[Patent Document 2] Japanese Laid-Open Patent Publication No. 2007-066969

[Patent Document 3] Japanese Laid-Open Patent Publication No. 2006-303373

[Patent Document 4] Japanese Laid-Open Patent Publication No. 2006-287923

### SUMMARY OF THE INVENTION

An object of the present invention is to provide a white light emitting diode, a white light emitting apparatus, and a linear illuminator that achieve emission of a light having a high degree of whiteness even with a white light emitting diode of a low degree of whiteness.

A white light emitting apparatus according to a first aspect includes: a first white light emitting diode emitting yellowish white; a second white light emitting diode emitting bluish white in the same direction of emission by the first white light emitting diode; and a current controller controlling drive currents of the first and second white light emitting diodes.

In the white light emitting apparatus according to a second aspect, the current controller controls duty ratios of outputs of the drive currents, in the first aspect.

In the white light emitting apparatus according to a third aspect, the current controller controls values of the drive currents, in the first aspect.

In the white light emitting apparatus according to a fourth aspect, each of the first and second white light emitting diodes includes: a blue light emitting diode chip; and wavelength conversion layer for wavelength conversion of a part of blue light from the blue light emitting diode chip into yellow light, in the first aspect.

In the white light emitting apparatus according to a fifth aspect, the wavelength conversion layer in the second white light emitting diode has a thickness smaller than that of the wavelength conversion layer in the first white light emitting diode, in the fourth aspect.

A white light emitting diode according to a sixth aspect includes: first and second blue light emitting diode chips; and a wavelength conversion layer for wavelength conversion of a part of blue light from the first and second blue light emitting diode chips into yellow light, wherein the wavelength conversion layer emits yellowish white after wavelength conversion of a part of blue light from the first blue light emitting diode chip into yellow light, and emits bluish white after wavelength conversion of a part of blue light from the second blue light emitting diode chip into yellow light.

In the white light emitting diode according to a seventh aspect, the wavelength conversion layer includes: a first fluorescent layer covering the first and second blue light emitting diode chips; and a second fluorescent layer covering only the second blue light emitting diode chip of the first and second blue light emitting diode chips, in the sixth aspect.

A white light emitting apparatus according to an eighth aspect includes: first and second blue light emitting diode chips; a wavelength conversion layer for wavelength conversion of a part of blue light from the first and second blue light emitting diode chips into yellow light; and a current controller controlling drive currents of the first and second blue light emitting diode chips, wherein color mixture with the yellow light obtained by the wavelength conversion of a part of blue light from the first blue light emitting diode chip by the wavelength conversion layer and the remained part of blue light from the first blue light emitting diode chip results in yellowish white, and color mixture with the yellow light obtained by the wavelength conversion of a part of blue light from the second blue light emitting diode chip by the wavelength conversion layer and the remained part of blue light from the second blue light emitting diode chip results in bluish white.

In the white light emitting apparatus according to a ninth aspect, the current controller controls duty ratios of outputs of the drive currents, in the eighth aspect.

In the white light emitting apparatus according to a tenth aspect, the current controller controls values of the drive currents, in the eighth aspect.

A linear illuminator according to a eleventh aspect includes: a white light emitting apparatus; and a light guide member guiding a light incident from the white light emitting apparatus and linearly illuminating an object to be illuminated, wherein the white light emitting apparatus includes: a first white light emitting diode emitting yellowish white; a second white light emitting diode emitting bluish white in the same direction of emission by the first white light emitting diode; and a current controller controlling drive currents of the first and second white light emitting diodes.

A linear illuminator according to a twelfth aspect includes: a white light emitting apparatus; and a light guide member guiding a light incident from the white light emitting apparatus and linearly illuminating an object to be illuminated, wherein the white light emitting apparatus includes: first and second blue light emitting diode chips; a wavelength conversion layer for wavelength conversion of a part of blue light from the first and second blue light emitting diode chips into yellow light; and a current controller controlling drive currents of the first and second blue light emitting diode chips, wherein color mixture with the yellow light obtained by the wavelength conversion of a part of blue light from the first blue light emitting diode chip by the wavelength conversion layer and the remained part of blue light from the first blue light emitting diode chip results in yellowish white, and color mixture with the yellow light obtained by the wavelength conversion of a part of blue light from the second blue light emitting diode chip by the wavelength conversion layer and the remained part of blue light from the second blue light emitting diode chip results in bluish white.

A linear illuminator according to a thirteenth aspect includes: a white light emitting diode; and a light guide member guiding a light incident from the white light emitting diode and linearly illuminating an object to be illuminated, wherein the white light emitting diode includes: first and second blue light emitting diode chips; and a wavelength conversion layer for wavelength conversion of a part of blue light from the first and second blue light emitting diode chips into yellow light, wherein color mixture with the yellow light obtained by the wavelength conversion of a part of blue light from the first blue light emitting diode chip by the wavelength conversion layer and the remained part of blue light from the first blue light emitting diode chip results in yellowish white, and color mixture with the yellow light obtained by the wavelength conversion of a part of blue light from the second blue light emitting diode chip by the wavelength conversion layer and the remained part of blue light from the second blue light emitting diode chip results in bluish white.

According to the above technologies, because an emission of a light having a high degree of whiteness due to a current control is obtained, a variation in chromaticity of an emitted white light can be allowed to some degree. Therefore, a white light emitting diode which could be considered to be defective before becomes usable, which improves its productivity. In other words, it allows an economical use of white light emitting diodes.

### BRIEF DESCRIPTION OF THE DRAWINGS

FIG. 1 is a perspective diagram illustrating a light source section of a white light emitting apparatus according to a first embodiment of the present invention;

FIG. 2 is a diagram illustrating one example of an electrical circuit driving the white light emitting apparatus according to the first embodiment of the present invention;

FIG. 3 is a chromaticity diagram illustrating a relationship between chromaticities of emitted lights from the white light emitting apparatus according to the first embodiment of the present invention;

FIG. 4 is a diagram illustrating a control of illumination duration of a white light emitting diode in the first embodiment of the present invention;

FIG. 5 is a cross sectional diagram illustrating a modified embodiment of the white light emitting apparatus according to the first embodiment of the present invention;

FIG. 6 is a perspective diagram illustrating a linear illuminator according to a second embodiment of the present invention;

FIG. 7 is a cross sectional diagram illustrating a contact-type image sensor unit in which the linear illuminator according to the second embodiment of the present invention is incorporated;

FIG. 8A is a diagram illustrating the relative illuminance between each of R, G, and B colors before an adjustment of illumination duration in the linear illuminator according to the second embodiment of the present invention;

FIG. 8B is a diagram illustrating the relative illuminance between each of R, G, and B colors after the adjustment of illumination duration in the linear illuminator according to the second embodiment of the present invention;

FIG. 9A is a diagram illustrating a method for manufacturing a white light emitting diode according to a third embodiment of the present invention (a configuration before a fluorescent layer is formed);

FIG. 9B is a diagram illustrating the method subsequent to FIG. 9A for manufacturing a white light emitting diode according to the third embodiment of the present invention (a configuration after a fluorescent layer is formed);

FIG. 10 is a diagram illustrating a state with the white light emitting diode according to the third embodiment of the present invention being mounted to a printed circuit board;

FIG. 11 is a chromaticity diagram illustrating a relationship between chromaticity of emitted lights from the white light emitting diode according to the third embodiment t of the present invention;

FIG. 12 is a perspective diagram illustrating a linear illuminator according to a fourth embodiment of the present invention;

FIG. 13 is a cross sectional diagram illustrating a contact-type image sensor unit in which the linear illuminator according to the fourth embodiment of the present invention is incorporated;

FIG. 14 is a cross sectional diagram illustrating one example of a white light emitting diode in the prior art; and

FIG. 15 is a chromaticity diagram illustrating a relationship between the degrees of whiteness of a white light emitting diode and identification areas.

### DETAILED DESCRIPTION OF THE PREFERRED EMBODIMENTS

The present invention was completed based on the study of property of a white light emitting diode having a blue LED chip and a fluorescent substance by the inventors of the present application, the study of a white light emitting diode, a white light emitting apparatus, and an illuminator for emitting white light that emit a high-power light having a uniform degree of whiteness, and a novel finding of a configuration of these which is easy to manufacture.

### First Embodiment

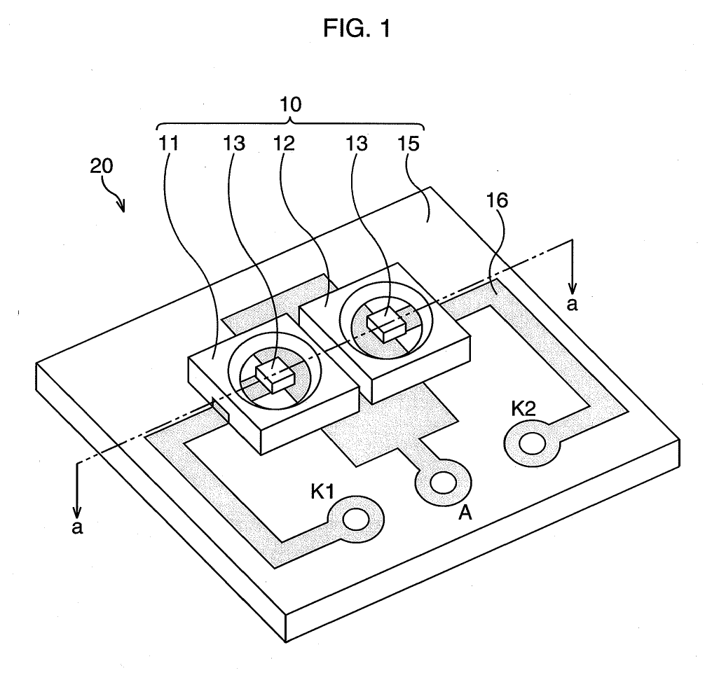

A white light emitting apparatus according to the first embodiment is provided with two or more white light emitting diodes. Each of the white light emitting diodes includes a blue LED chip, and a fluorescent layer which is excited by a radiation light emitted by the blue LED chip and emits a yellow light. Yellow is a complementary color of blue. In the first embodiment, a white light emitting apparatus 20 having the two or more white light emitting diodes will be explained below with reference to FIGS. 1 to 5.

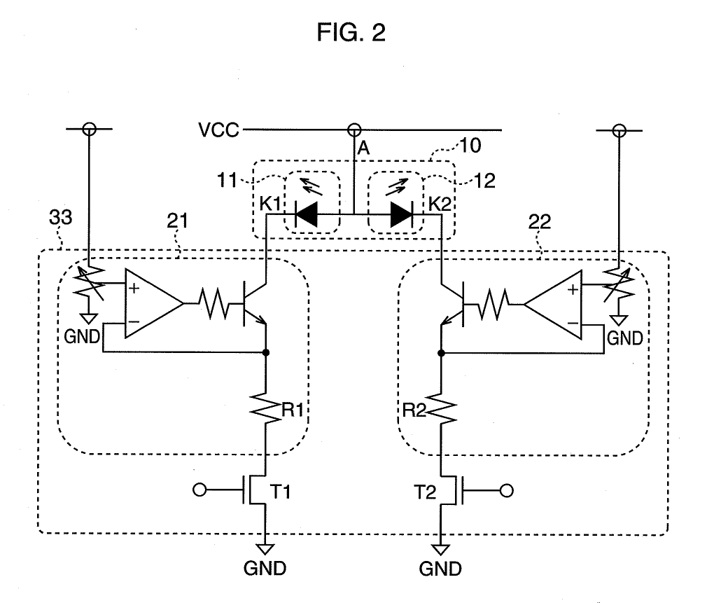

FIG. 1 illustrates a light source section 10 of the white light emitting apparatus 20 of the first embodiment. In the white light emitting apparatus 20, a first white light emitting diode 11 and a second white light emitting diode 12 are adjacently mounted to a printed circuit board 15. The first white light emitting diode 11 emits a white light which is more yellowish and deviated from the white point on a chromaticity diagram. The second white light emitting diode 12 emits a white light which is more bluish and deviated from the white point on a chromaticity diagram. The white light emitting diodes 11 and 12 are also arranged to emit light in parallel to each other and in the same direction substantially. The printed circuit board 15 is provided with wiring 16 for electric supply, including an anode line which is common to the two white light emitting diodes 11 and 12, and two cathode lines connected to each of the white light emitting diodes 11 and 12. The anode line and the two cathode lines are connected to an external current control section (see FIG. 2) through terminals A, K1, and K2 respectively. The current control section causes the white light emitting diodes 11 and 12, which constitute the light source section 10 of the white light emitting apparatus 20, to be driven.

The first white light emitting diode 11 may be, for example, a white light emitting diode that is recognized to emit a yellowish white light in accordance with a recognition method by lighting a constant current of 10 mA among the white light emitting diodes of white LEDs each of which is a commercially available surface mount LED package having a longitudinal dimension of about 2.0 mm and a lateral dimension of about 1.2 mm (NESW007A, manufactured by Nichia Corporation). The second white light emitting diode 12 may be, for example, a white light emitting diode that is recognized to emit a bluish white light in accordance with a recognition method by lighting a constant current of 10 mA among the white light emitting diodes of white LEDs each of which is a commercially available surface mount LED package having a longitudinal dimension of about 2.0 mm and a lateral dimension of about 1.2 mm (NESW007A, manufactured by Nichia Corporation).

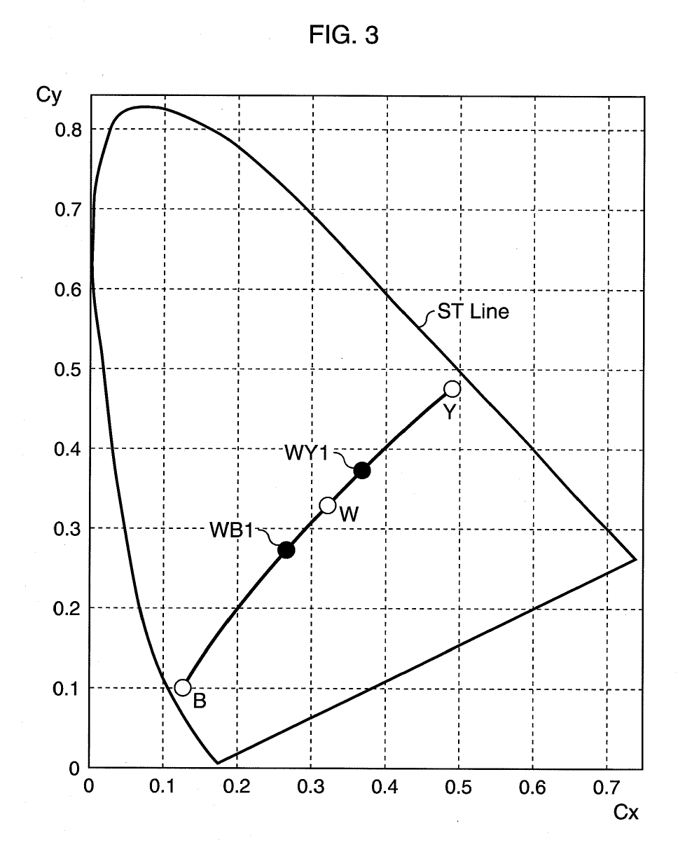

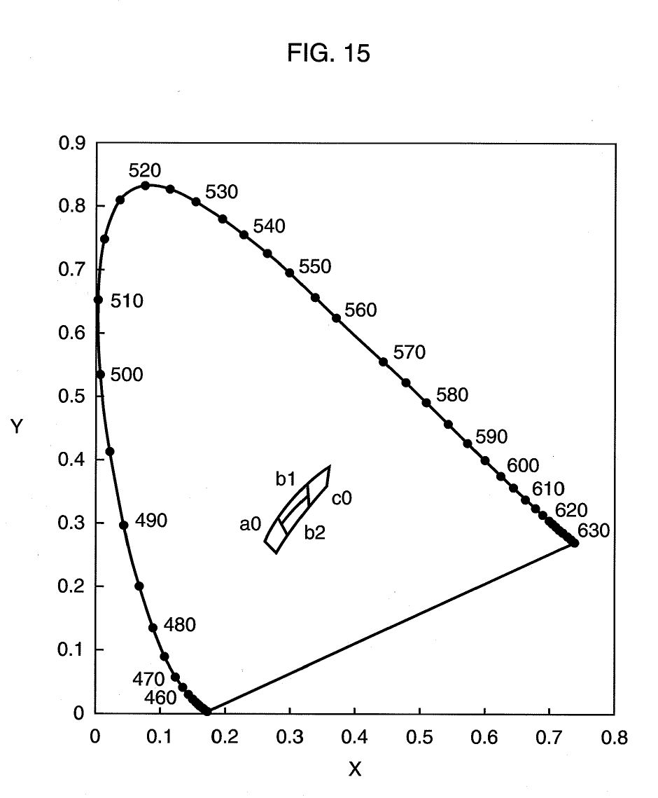

Now, the relationship between chromaticity of the lights emitted by each of the white light emitting diodes 11 and 12 of the first embodiment will be explained below using the chromaticity diagrams of FIG. 3 and FIG. 15. For the first white light emitting diode 11, a white light emitting diode is selected so that a blue light, which is emitted from a blue LED chip therein and does not interact with fluorescent particles in a fluorescent layer, and a yellow light, which is generated by wavelength conversion after the interaction with the fluorescent particles, produce a color mixture that has its color distribution on the yellow side of the white point. For the second white light emitting diode 12, similarly, a white light emitting diode is selected so that a blue light and a yellow light produce a color mixture that has its color distribution on the blue side of the white point.

The above relationship will be explained below using the chromaticity diagram illustrated in FIG. 3. In the chromaticity diagram, the chromaticity point of a yellow light (560 nm) after wavelength conversion by a YAG fluorescent substance is shown by Y, and the chromaticity point of a blue light emitted from a blue LED chip (one representative from the range of 450 nm to 470 nm) is shown by B. When a curved line YB is defined on the assumption that both of the chromaticity points Y and B are positioned near a curved line ST, which illustrates a monochromatic light in the chromaticity diagram, the curved line YB passes near the white color chromaticity point W (x=0.33, y=0.33). This is because the YAG fluorescent substance is used to obtain a fluorescent white light by compositing a light emitted from a blue LED chip and a light emitted by the fluorescent substance.

The chromaticity point WY1 of the color mixture of the light emitted from the first white light emitting diode 11 is substantially positioned on the curved line WY, which is connected between the white point W and the yellow point Y. The chromaticity point WB1 of the color mixture of the light emitted from the second white light emitting diode 12 is substantially positioned on the curved line WB, which is connected between the white point W and the blue point B.

Meanwhile, one example of chromaticity areas that can be selected with luminescence thereof in a selection using a constant current of 10 mA by a selector is illustrated in FIG. 15. Therefore, as the first white light emitting diode 11, a light emitting diode that has a chromaticity coordinate: 0.33<Cx≦0.36; 0.33<Cy≦0.38 when driven at a constant current of 10 mA is preferably used, with the chromaticity coordinate being substantially on the curved line YB. Also, as the second white light emitting diode 12, a light emitting diode that generally has a chromaticity coordinate: 0.27≦Cx<0.33; 0.26≦Cy<0.33 when driven at a constant current of 10 mA is preferably used, with the chromaticity coordinate being substantially on the curved line YB. As described above, in the present invention, the yellowish white means white color the position of which is substantially close to the white point on the curved line WY, while the bluish white means white color the position of which is substantially close to the white point on the curved line WB.

FIG. 2 is a diagram illustrating one example of an electrical circuit driving the white light emitting apparatus 20. The electrical circuit includes the light source section 10 and a current control section 33. The light source section 10 corresponds to the part illustrated in FIG. 1. The current control section 33 includes current control sections that are separately provided to set a current for each of the white light emitting diodes 11 and 12. For example, current regulating circuits 21 and 22 are connected in parallel to each of the white light emitting diodes 11 and 12 via two cathode terminals K1 and K2 of the light source section 10, respectively. Also, transistors T1 and T2 turning ON/OFF each of the white light emitting diodes 11 and 12 are connected to the current regulating circuits 21 and 22, respectively. The transistors T1 and T2 are connected to ground GND.

Each of the current regulating circuits 21 and 22 are, for example, provided with an operation amplifier, a transistor, and current-limiting resistor R1 or R2. The current control section 33 causes a constant current that is defined for each of the white light emitting diodes 11 and 12 to be applied to each of the white light emitting diodes 11 and 12, so as to control the lighting of each of the white light emitting diodes 11 and 12 by a pulse width modulation (hereinafter, simply referred to as PWM) method. Such current control section 33 functions as a current control means.

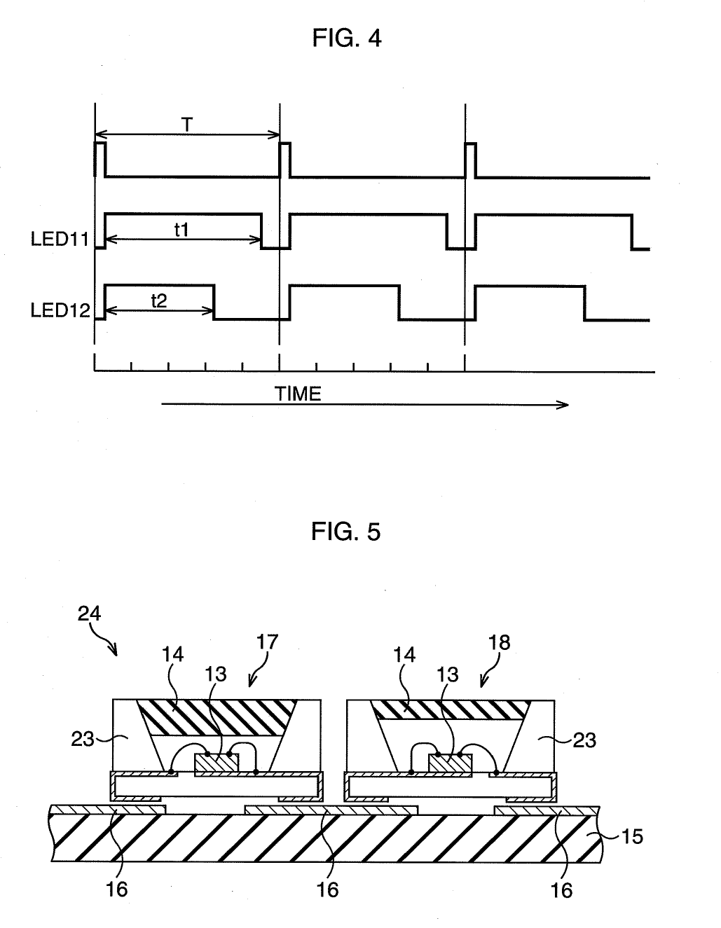

Next, the current control operation for obtaining a color mixture of emitted lights from the white light emitting apparatus 20 of the first embodiment that is substantially adjusted to the white point on a chromaticity diagram will be explained below. FIG. 4 is a timing chart illustrating a control of the illumination durations of the white light emitting diodes 11 and 12 by a pulse width modulation (PWM) method.

First, the white light emitting apparatus 20 is operated with a duration of pulse T being set to be 10 milliseconds, a current driving the white light emitting diodes 11 and 12 being set to be 10 mA, an illumination duration t1 of the white light emitting diode 11 being set to be 9 milliseconds for each cycle. The drive currents of the white light emitting diodes 11 and 12 are set by the current regulating circuits 21 and 22 respectively, and the illumination duration t1 is controlled by the transistor T1.

Next, a sensor measuring chromaticity is installed at a position, above the light emitting surface of the white light emitting apparatus 20, which is separated from the two white light emitting diodes 11 and 12 by a distance so that the emitted lights are sufficiently mixed with each other, and a measurement of chromaticity is started, with a time for receiving time being set to be several tens times that of the duration T.

Then, an illumination duration t2 of the white light emitting diode 12 for each cycle is controlled by the transistor T2, to find an illumination duration t2 for a chromaticity measurement by a light emitted from the white light emitting apparatus 20: Cx=0.33, and Cy=0.33, approximately.

Here, in order to allow a color mixture of emitted lights from the white light emitting apparatus 20 to substantially reach the white point on a chromaticity diagram, the PWM control by the current control section 33 may be used to cause the white light emitting diode 11 to light in accordance with a duty ratio D1=t1/T, and the white light emitting diode 12 to light in accordance with a duty ratio D2=t2/T.

As described above, according to the first embodiment, an emission of a light having a high purity of whiteness, which was difficult by one white light emitting diode, is achieved, and the high power white light emitting apparatus 20 is attained. Also, depending on the control of a drive current of each of the white light emitting diodes 11 and 12, the chromaticity coordinate of a light emission from the white light emitting apparatus 20 can be changed from the chromaticity point WY1 to the chromaticity point WB1 along the curved line YB.

As the current control in the white light emitting apparatus 20, instead of the control with the PWM method, the amounts of currents driving the white light emitting diodes 11 and 12 may be controlled. The amounts of currents can be controlled by the current regulating circuits 21 and 22. Alternatively, the control with the PWM method and the control of the current amounts may be combined.

Next, a modified embodiment of the first embodiment will be explained below with reference to FIG. 5. A white light emitting apparatus 24 according to the modified embodiment includes two types of white light emitting diodes 17 and 18 adjacently mounted on the printed circuit board 15, the diodes 17 and 18 being individually provided with a fluorescent layer 14 of a different thickness from each other. That means the first white light emitting diode 17 is provided with a thicker fluorescent layer 14, and the color mixture of the lights emitted from the white light emitting diode 17 is yellowish white, similar to the white light emitting diode 11. The second white light emitting diode 18 is provided with a thinner fluorescent layer 14, and the color mixture of the lights emitted from the white light emitting diode 18 is bluish white, similar to the white light emitting diode 12. The thickness of the fluorescent layer 14 is controlled during the manufacture of the white light emitting diodes 17 and 18, for example.

The white light emitting apparatus 24 in which the current control section 33 is connected to the light source section 10 including the above described white light emitting diodes 17 and 18 therein can also provide high purity whiteness as in the case of the first embodiment. In addition, as compared with the white light emitting diode with one blue LED chip, a higher power emission of white light can be obtained.

### Second Embodiment

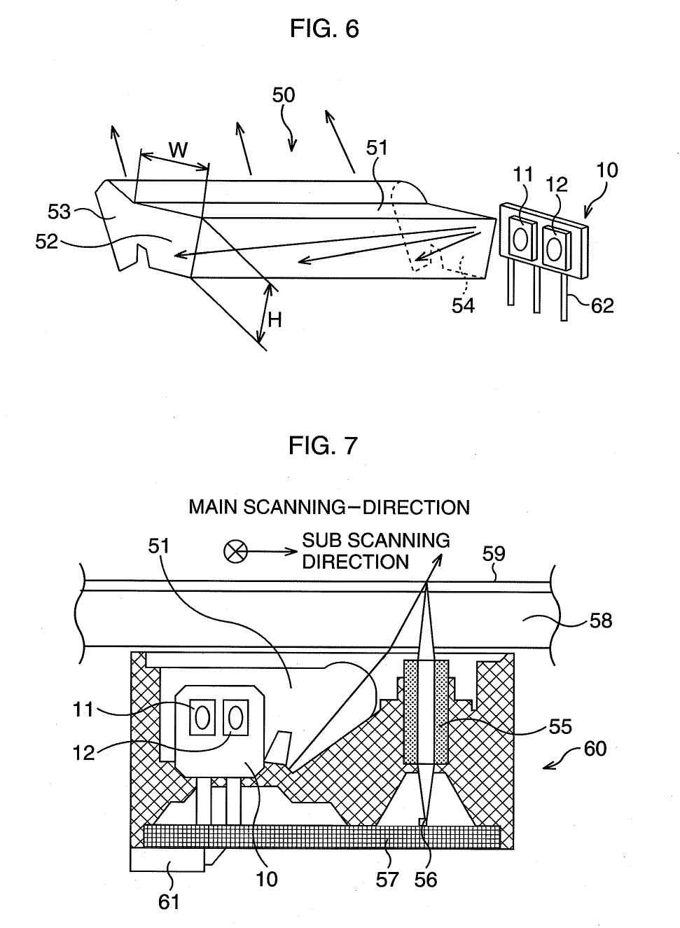

A linear illuminator 50 according to a second embodiment uses the white light emitting apparatus 20 according to the first embodiment. The linear illuminator 50 will be explained in detail below with reference to FIGS. 6 to 8.

The linear illuminator 50 of the second embodiment is used to illuminate a surface of a manuscript such as a paper in an image reading apparatus, for example. The linear illuminator 50 is, as illustrated in FIG. 6, provided with a bar-shaped light guide member 51 that is formed of a transparent material and has a light incident surface 54 at one end thereof, and the light source section 10 disposed toward the light incident surface 54. The light source section 10 is connected with the current control section 33 via terminal lead 62 as in the case of the first embodiment (not illustrated in FIG. 6). The light guide member 51 is provided with a light guiding section 52 guiding an incident light from the light incident surface 54 in the longitudinal direction of the light guide member, and a light emitting section 53 linearly emitting the light from the light guiding section 52 in the longitudinal direction.

In order to improve the light yield of the light guide member 51 from the light incident surface 54 into the light guide member 51, the light source section 10 is designed to have a light emitting surface of a size that can be included in the light incident surface 54 with margin. For example, in the case with the light emitting surface of the light source section 10 having a size of 2.5 mm (horizontal direction)×2 mm (vertical direction), the light guide member 51 is designed to have a light emitting surface having a size of 3.5 mm (horizontal direction)×2.5 mm (vertical direction)

The light guide member 51 may be, for example, a member for a light source that has light emitting diodes of three wavelengths (for example, for red, green, and blue) arranged thereon (at different positions). That means a light guide member designed for linear illumination may be used, in which lights from a light source are incident to a light incident surface, and proper reflection and scattering occur in the light guide member for each wavelength, so that a light is emitted with the outputs of the wavelengths being uniformly distributed in the longitudinal direction thereof. A light guide member having such a function is described in detail in Patent Document 4 (Japanese Laid-Open Patent Publication No. 2006-287923), for example.

Therefore, even when there is a difference in the wavelengths of emitted lights from the two white light emitting diodes 11 and 12 of the light source section 10 in the white light emitting apparatus 20, which are used as light sources, and also the central points of the two emitted lights are not at the same position, the light guide member 51 allows the colors of the incident lights from the light incident surface 54 to be well mixed so as to emit a linear illumination light that has a uniform color distribution of whiteness.

The inventors of the present invention checked the above described effect of the linear illuminator 50 of the second embodiment in the following procedure. First, as illustrated in FIG. 7, the linear illuminator 50 was incorporated in a contact image sensor unit (hereinafter, simply referred to as CIS unit) 60 that constitutes an image reading apparatus. Not illustrated, but the current control section 33 of the white light emitting apparatus 20 was connected via the connector 61.

The CIS unit 60 was used to cause a light reflected by the paper manuscript 59 to be focused on a line sensor 56 by a lens array 55. The line sensor 56 was the one configured with three linear rows of pixels that separately receive a color of red (R), green (G), or blue (B) for photoelectric conversion (illustration is omitted). The line sensor 56 has three color filters that have pass bands for RGB and are disposed on each row of pixels. Therefore, each row of pixels functions with spectral sensitivity corresponding to each of the R, B, and G colors. Such sensor array is described in Japanese Patent No. 3990437, for example.

Therefore, the CIS unit 60 is able to disperse the white light reflected by the paper manuscript 59 into each of the R, B, and G colors, and measure the illuminance for each pixel of the row of pixels arranged in the longitudinal direction thereof. The measured illuminance value for each pixel can be represented as illuminance distribution for the area from one end surface on the light incident surface side to the other end surface in the longitudinal direction of the light guide member 51.

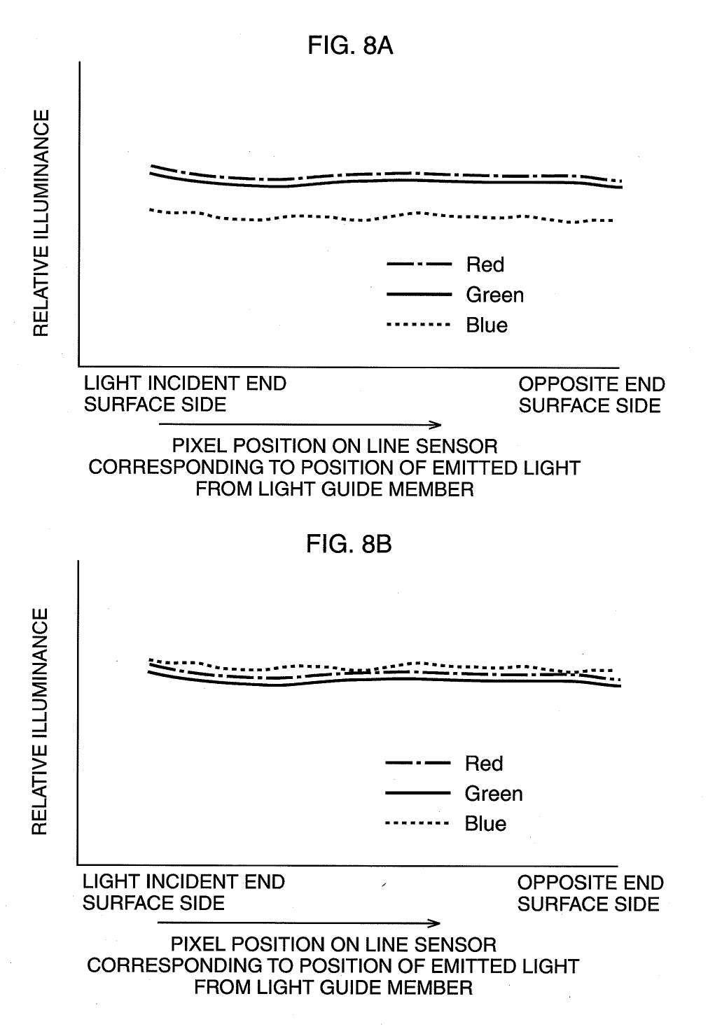

Next, as in the case of First Embodiment, after the paper manuscript 59 was replaced with a predetermined white paper for reference, both of the white light emitting diodes 11 and 12 were simultaneously driven with the current control section 33. And the illumination light of the linear illuminator 50 was measured for the relative illuminance of each of R, G, and B colors as illuminance distribution in the linear direction (FIG. 8A). In the measurement, the currents applied to both of the white light emitting diodes 11 and 12 were controlled to be 10 mA. The measured result for illuminance distributions showed generally uniform distributions in the longitudinal direction with approximately the same values of relative illuminance for red and green colors as illustrated in FIG. 8A, but for blue color, the result showed a substantially uniform distribution in the longitudinal direction with a lower relative illuminance as compared to those of red and green colors.

Then, as in the case of the first embodiment, after the illumination duration for each cycle of the white light emitting diode 12, that is the duty ratio D2, was controlled, the relative illuminance of each of R, G, and B colors could be controlled to have substantially the same distribution, as illustrated in FIG. 8B.

The above result of the second embodiment showed that the linear illuminator 50 for illumination with the relative illuminance of each of R, G, and B colors being well balanced can be manufactured.

In a conventional linear illuminator that uses one white light emitting diode as a light source, often a white light emitting diode for pure whiteness is selected with efforts by sacrificing cost, or a white light emitting diode having deviation in color distribution of whiteness is selected to obtain a white illumination light of a low quality as a result. To the contrary, according to the linear illuminator 50 of the second embodiment, it was found that when commercially available white light emitting diodes having deviation in color distribution of whiteness are combined and the illumination duration is controlled by controlling a duty ratio by the PWM method, for example, a highly pure white illumination light can be readily obtained.

The combination of the white light emitting diodes 11 and 12 may be accomplished by selecting a diode emitting a yellowish white light and a diode emitting a bluish white light, and the chromaticity value of each diode which is inherent property of a white light emitting diode may not be determined at the point of time of selection. Therefore, the white light emitting diodes 11 and 12 may be any diode that emits a light that has a position generally on the curved line YB in the chromaticity diagram of FIG. 3, even if the position is deviated from the white point to a large degree. As a result, white light emitting diodes that have been determined to be defective become usable without discarding, which leads to enhanced productivity of white light emitting diodes.

### Third Embodiment

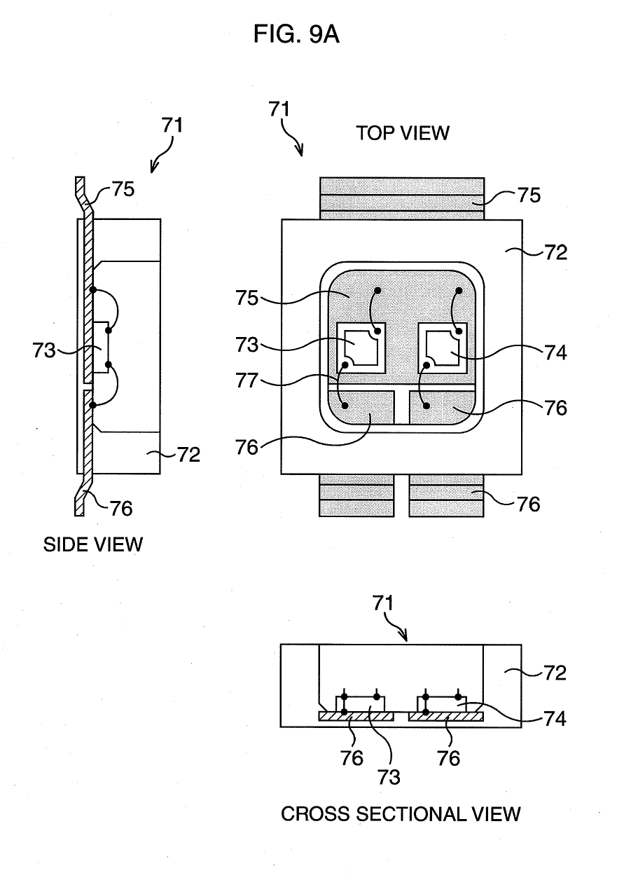

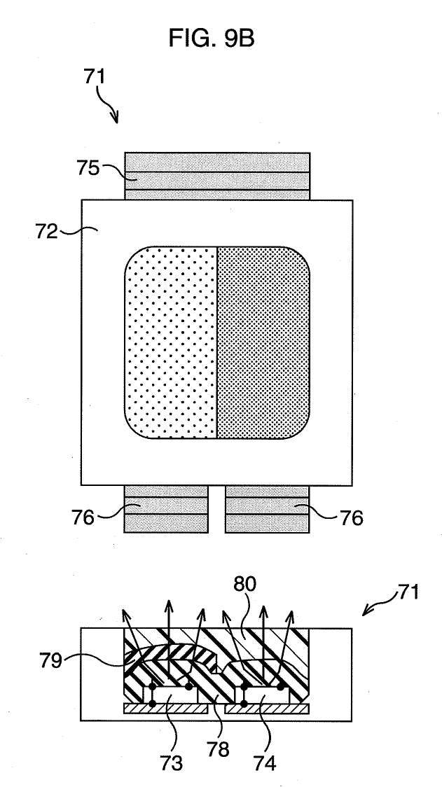

In a third embodiment, two blue LED chips are mounted to one package, and a YAG fluorescent layer covers each of the blue LED chips and has a thickness different from those of others. With reference to FIGS. 9A and 9B, a method for manufacturing a white light emitting diode 71 of the third embodiment will be explained below.

A package 72 is formed of a resin into a box shape with the top thereof being open, and the package 72 has wiring of a lead frame at the bottom thereof, so that an anode wiring 75 of a lead frame at the bottom has a first blue LED chip 73 and a second blue LED chip 74 disposed thereon. Then, the cathode terminal and the anode terminal thereof are connected to the cathode wiring 76 and the anode wiring 75 of the lead frame respectively by using a wire-bonding method for example, to be mounted (FIG. 9A). The top opening may have a dimension of about 2.5 mm or less in the longitudinal and lateral directions thereof, for example.

Next, a resin solution for fluorescent layer is prepared by mixing a predetermined amount of YAG fluorescent particles into a clear thermosetting transparent resin, which is coated to both of the blue LED chips 73 and 74 for covering. Then, the resin solution for fluorescent layer is subjected to a heat cure procedure, so that a first fluorescent layer 78 is formed as illustrated in FIG. 9B. Then, a resin solution for fluorescent layer which is the same as the above resin solution for fluorescent layer is coated to the surface of the fluorescent layer 78 to cover only the upper side of the blue LED chip 73. Then, the resin solution for fluorescent layer is subjected to a heat cure procedure, so that a second fluorescent layer 79 is formed. Then, a seal body 80 is formed on the fluorescent layers 78 and 79 using the same thermosetting transparent resin as that included in the resin solution for fluorescent layer. In this way, as illustrated in FIG. 9B, the white light emitting diode 71 is made.

The thicknesses of the fluorescent layers 78 and 79 may be determined in advance as follows, for example. First, a plurality of blue LED chips that are the same products as the blue LED chips 73 and 74 are provided, and fluorescent layers having different thicknesses from each other are formed using the resin solution for fluorescent layer that is prepared as described above. As a result, a plurality of white light emitting diodes for evaluation can be obtained. Next, the white light emitting diodes for evaluation are caused to emit a light at a predetermined current, so that the diodes that produce a color mixture of bluish white without fail with the blue light, which does not interact with the fluorescent particles, and the yellow light, which interacts with the fluorescent particles in the fluorescent layer for wavelength conversion, and a range of the thickness of the fluorescent layer 78 is determined based on the thicknesses of the fluorescent layers. Next, a plurality of white light emitting diode that has the fluorescent layer 78 having a thickness within the range formed on each blue LED chip are provided, and a fluorescent layer is formed on each diode with the resin solution for fluorescent layer that is prepared as described above. As a result, a plurality of white light emitting diodes for evaluation can be newly obtained. Next, each of the white light emitting diodes for evaluation is caused to emit a light at a predetermined current, so that the diodes that produce a color mixture of yellowish white without fail with the blue light, which does not interact with the fluorescent particles, and the yellow light, which interacts with the fluorescent particles in the fluorescent layer for wavelength conversion, and based on the thicknesses of the fluorescent layers, a range of the thickness of the fluorescent layer 79 is determined.

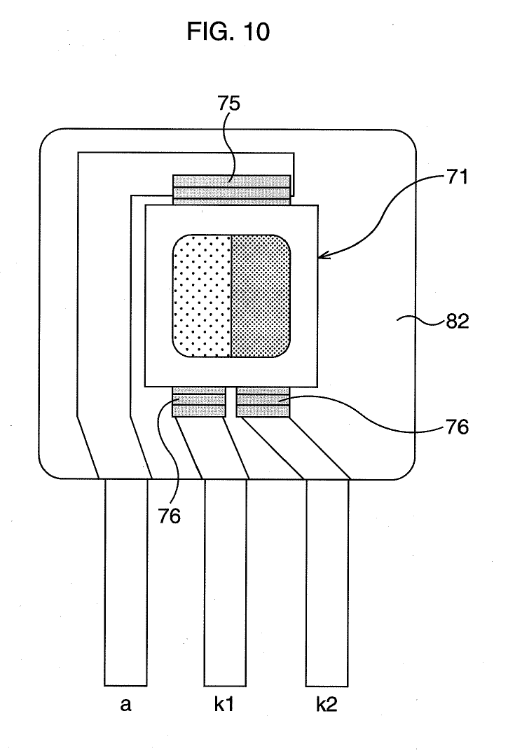

The white light emitting diode 71 made as described above may be used by mounting to a printed circuit board 82 as illustrated in FIG. 10, for example. The light emitting diode 71 may be driven by the current control section 33 of the first embodiment, for example, and is individually connected to a lead wirings a of the anode wiring 75 and the lead wirings k1, k2 of the two cathode wirings 76. In the case, the white light emitting apparatus having the white light emitting diode 71 has an electrical circuit configuration that is equal to that having the blue LED chips 73 and 74 instead of the white light emitting diodes 11 and 12 of FIG. 2.

The degree of whiteness of the light emitted from the white light emitting diode 71 made as described above may be controlled as follows. First, the current control section 33 is used to set the current value which is applied to the blue LED chips 73 and 74 to be 20 mA, and the PWM method similar to that in the first embodiment is used to cause both of the blue LED chips 73 and 74 to be driven. Then, the illumination duration of each of the blue LED chips 73 and 74 for each cycle is controlled to determine a duty ratio to drive each of the blue LED chips 73 and 74 so that the light emitted from the white light emitting diode 71 has an average wavelength distribution (the color mixture) generally at the white point.

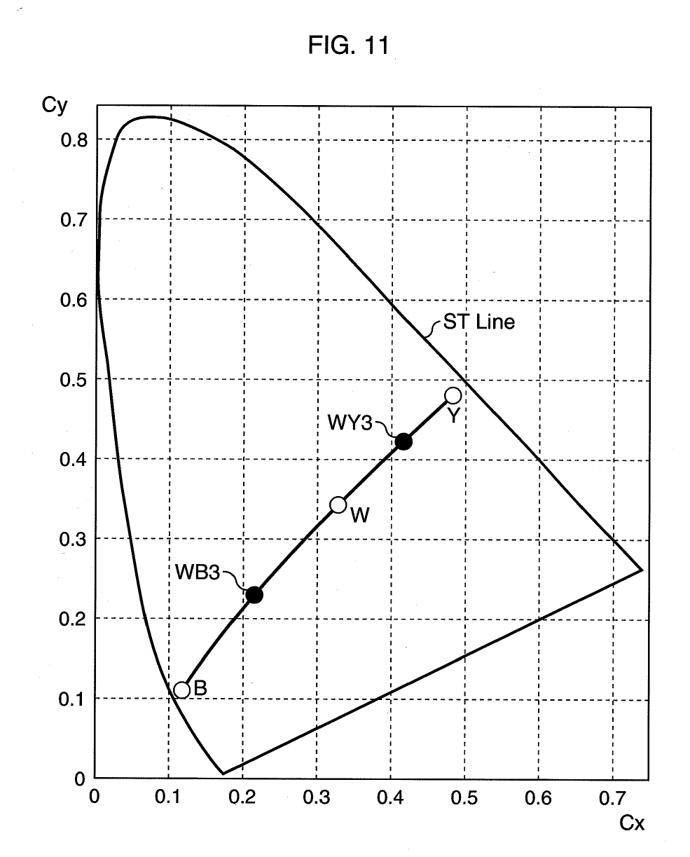

The relationship can be explained with reference to the chromaticity diagram of FIG. 11 as follows. The color mixture of the light emitted from the white light emitting diode 71 when only the blue LED chip 73 is lit by applying a current of 20 mA is detected as a chromaticity point WY3, which is substantially positioned on the curved line WY. Similarly, the color mixture of the light emitted from the white light emitting diode 71 when only the blue LED chip 74 is lit by applying a current of 20 mA is detected as a chromaticity point WB3, which is substantially positioned on the curved line WB. This is because the thicknesses of the fluorescent layers 78 and 79 are adequately defined. The coordinates of the chromaticity points WY3 and WB3 on the chromaticity diagram are (Cx=0.36 or more, Cy=0.39 or more), and (Cx=0.26 or less, Cy=0.25 or less), for example, respectively. Therefore, the chromaticity coordinates may be outside the chromaticity areas a0, b1, b2, and c0 in FIG. 15 that are allowed by selection.

Next, the duty ratios of both of the blue LED chips 73 and 74 in a PWM method driving are individually controlled, and the illumination duration is detected which results in a chromaticity measurement approximately equal to the whiteness point (Cx=0.33, Cy=0.33) for the color mixture of the light emitted from the white light emitting diode 71.

As described above, the white light emitting diode 71 of the third embodiment includes two blue LED chips 73 and 74 therein, and has YAG fluorescent layers 78 and 79 that cover the chips 73 and 74, and have adequately defined thicknesses. And the control of the duty ratio for lighting the blue LED chip 73, which is covered with both of the fluorescent layers 78 and 79, allows the amount of the emitted yellowish white light to be controlled. Also, the control of the duty ratio for lighting the blue LED chip 74, which is covered with only the fluorescent layer 78, allows the amount of the emitted bluish white light to be controlled. The controls make the color mixture of the light emitted from the white light emitting diode 71 fall on the white point W.

As described above, according to the white light emitting diode 71 of the third embodiment, a white light emission can be obtained without special caring about the variation in the inherent wavelengths of the light emitted from the blue LED chip, the variation in the yellow wavelength due to the formation of the fluorescent layers, and the like. Furthermore, the light emission from the white light emitting diode 71 can be readily controlled to be enhanced to a high-quality white light emission. In addition, as compared with the white light emitting diode with one blue LED chip, a higher power emission of white light can be obtained.

In the third embodiment, the light emission of the white light emitting diode 71 when only the blue LED chip 73 is driven at 20 mA is, as illustrated in FIG. 11, represented by the chromaticity point WY3 for yellowish white without fail. Similarly, the light emission of the white light emitting diode 71 when only the blue LED chip 74 is driven is, as illustrated in FIG. 11, represented by the chromaticity point WB3 for bluish white without fail. When the thicknesses of the fluorescent layers 78 and 79 are adequately determined and reliable yellow and blue colors are obtained, the chromaticity points WY3 and WB3 may be set at the positions separated from the chromaticity point WY1 for “yellowish white” and the chromaticity point WB1 for “bluish white” in the first embodiment respectively (FIG. 3) based on the chromaticity point W for white color as a reference. This is because the control of the drive currents that are applied to each of the blue LED chips 73 and 74 allows the chromaticity of the light emitted from white light emitting diode 71 also to reach the white point W as in the case of the first embodiment. Furthermore, according to the white light emitting diode 71 of the third embodiment, the chromaticity of emitted light can be controlled within a range from the chromaticity point WY3 to the chromaticity point WB3 along the curved line YB, which is wider than that of the first embodiment.

In the third embodiment, the ratio of wavelength conversion of the blue lights from the blue LED chips 73 and 74 to yellow lights is controlled using the thicknesses of the fluorescent layers 78 and 79, but the ratio may be controlled by the concentration of YAG fluorescent particles dispersed in the fluorescent layers 78 and 79. Also, in the third embodiment, the amounts of the emitted yellowish light and the emitted bluish light are controlled using the illumination duration per pulse, but may be controlled using the current values applied to the blue LED chips 73 and 74.

### Fourth Embodiment

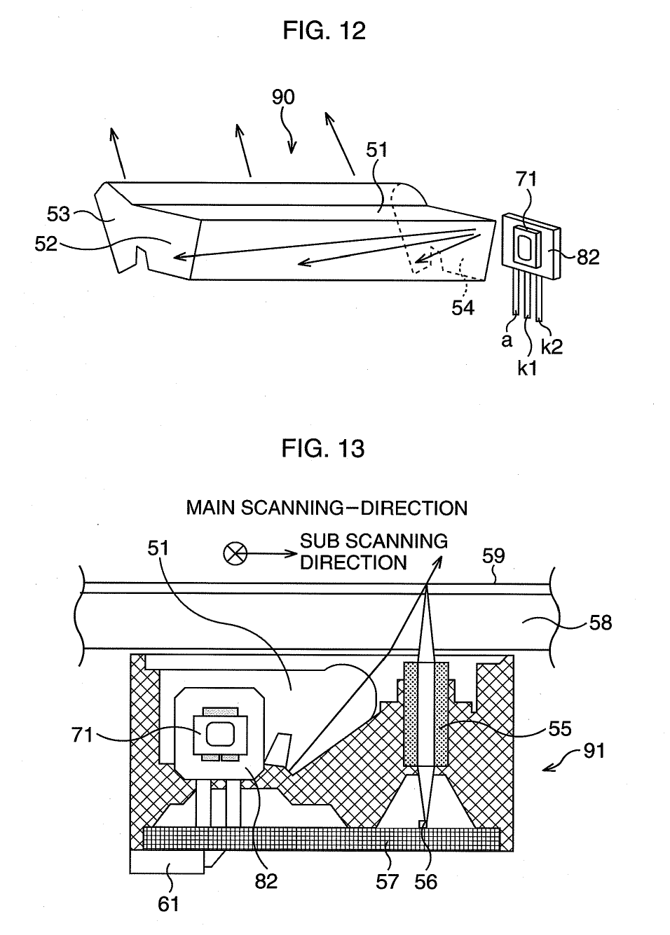

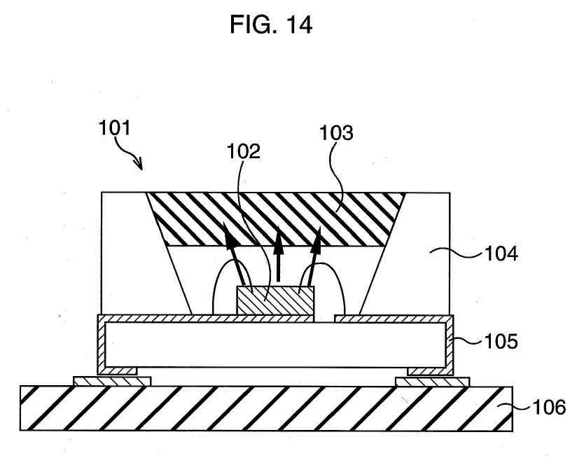

A linear illuminator 90 according to a fourth embodiment uses the white light emitting diode 71 according to the third embodiment. The linear illuminator 90 will be explained below in detail with reference to FIGS. 12 and 13.

The linear illuminator 90 of the fourth embodiment is also used to illuminate a surface of a manuscript such as a paper in an image reading apparatus, for example. The linear illuminator 90 is configured with a printed circuit board 82 to which the white light emitting diode 71 according to the third embodiment is mounted, instead of the light source section 10 in the second embodiment, as illustrated in FIG. 12.

The linear illuminator 90 incorporated in a CIS unit 91 provides the image reading apparatus illustrated in FIG. 13. Not illustrated, but similar to the second embodiment, the current control section 33 is connected via the connector 61. Other configurations are similar to those in the second embodiment.

Therefore, even in the case where there is a difference in wavelengths of emitted lights between the blue LED chips 73 and 74 in the white light emitting diode 71 used as a light source and the two central points of the emitted lights are not at the same position, the light guide member 51 is able to emit a linear illumination light of uniformly distributed color of whiteness after sufficient color mixture of incident lights from the light incident surface 54.

The inventors of the present invention checked the above described effect of the linear illuminator 90 of the fourth embodiment in the following procedure. As in the case of the second embodiment, the linear illuminator 90 was incorporated in the CIS unit 91 that constitutes an image reading apparatus.

Next, as in the case of the second embodiment, after the paper manuscript 59 was replaced with a predetermined white paper for reference, the blue LED chips 73 and 74 with the current control section 33 were simultaneously driven at a current value of 20 mA using the PWM method. Then the relative illuminance of each of R, G, and B colors and the illuminance distribution in the linear direction were measured.

Then, similar to the second embodiment, based on the measured result, each of the duty ratios of the current pulses for driving the blue LED chips 73 and 74 were adjusted, as the result of that the relative illuminance of each of R, G, and B colors could be adjusted to be generally uniformly distributed across the entire width of the original paper copy 59.

The above result of the present Fourth Embodiment showed the manufacture of the linear illuminator 90 can be achieved that emits a light with the relative illuminance of each of R, G, and B colors being well balanced using the white light emitting diode 71.

### INDUSTRIAL APPLICABILITY

A white light emitting diode and a white light emitting apparatus of the present invention are usable as a light source that achieves a highly precise whiteness and high power even with a conventional blue LED chip that emits a light that has deviation in color distribution from a white point or a white light emitting diode that emits a light having deviation in color distribution from a white point due to the property of a fluorescent layer and the like. Furthermore, according to a linear illuminator that is a combination of a white light emitting diode or a white light emitting apparatus of the present invention and a light guide member, an illumination can be achieved with a well balanced relative illuminance of each of R, G, and B colors.

A white light emitting diode, a white light emitting apparatus, and a linear illuminator in which either of the white light emitting diode and the white light emitting apparatus is incorporated of the present invention are usable as a linear illuminator incorporated in an image reading apparatus for scanner, facsimile or the like. A plurality of white light emitting diodes or white light emitting apparatuses of the present invention that are arranged in parallel are also usable as a backlight source of liquid crystal display and the like.

What is claimed is:

1. A white light emitting apparatus, comprising:
a first white light emitting diode emitting yellowish white;
a second white light emitting diode emitting bluish white in the same direction of emission by the first white light emitting diode; and
a current controller controlling drive currents of the first and second white light emitting diodes.

2. The white light emitting apparatus according to claim 1, wherein the current controller controls duty ratios of outputs of the drive currents.

3. The white light emitting apparatus according to claim 1, wherein the current controller controls values of the drive currents.

4. The white light emitting apparatus according to claim 1, wherein
each of the first and second white light emitting diodes comprises:
a blue light emitting diode chip; and
a wavelength conversion layer for wavelength conversion of a part of blue light from the blue light emitting diode chip into yellow light.

5. The white light emitting apparatus according to claim 4, wherein the wavelength conversion layer in the second white light emitting diode has a thickness smaller than that of the wavelength conversion layer in the first white light emitting diode.

6. A white light emitting diode, comprising:
first and second blue light emitting diode chips; and
a wavelength conversion layer for wavelength conversion of a part of blue light from the first and second blue light emitting diode chips into yellow light, wherein
the wavelength conversion layer
emits yellowish white after wavelength conversion of a part of blue light from the first blue light emitting diode chip into yellow light, and
emits bluish white after wavelength conversion of a part of blue light from the second blue light emitting diode chip into yellow light.

7. The white light emitting diode according to claim 6, wherein
the wavelength conversion layer comprises:
a first fluorescent layer covering the first and second blue light emitting diode chips; and
a second fluorescent layer covering only the second blue light emitting diode chip of the first and second blue light emitting diode chips.

8. A white light emitting apparatus, comprising:
first and second blue light emitting diode chips;
a wavelength conversion layer for wavelength conversion of a part of blue light from the first and second blue light emitting diode chips into yellow light; and
a current controller controlling drive currents of the first and second blue light emitting diode chips, wherein
color mixture with the yellow light obtained by the wavelength conversion of a part of blue light from the first blue light emitting diode chip by the wavelength conversion layer and the remained part of blue light from the first blue light emitting diode chip results in yellowish white, and
color mixture with the yellow light obtained by the wavelength conversion of a part of blue light from the second blue light emitting diode chip by the wavelength conversion layer and the remained part of blue light from the second blue light emitting diode chip results in bluish white.

9. The white light emitting apparatus according to claim 8, wherein the current controller controls duty ratios of outputs of the drive currents.

10. The white light emitting apparatus according to claim 8 wherein, the current controller controls values of the drive currents.

11. A linear illuminator, comprising:
a white light emitting apparatus; and
a light guide member guiding a light incident from the white light emitting apparatus and linearly illuminating an object to be illuminated, wherein
the white light emitting apparatus comprises:
a first white light emitting diode emitting yellowish white;
a second white light emitting diode emitting bluish white in the same direction of emission by the first white light emitting diode; and
a current controller controlling drive currents of the first and second white light emitting diodes.

12. A linear illuminator, comprising:
a white light emitting apparatus; and
a light guide member guiding a light incident from the white light emitting apparatus and linearly illuminating an object to be illuminated, wherein
the white light emitting apparatus comprises:
first and second blue light emitting diode chips;
a wavelength conversion layer for wavelength conversion of a part of blue light from the first and second blue light emitting diode chips into yellow light; and
a current controller controlling drive currents of the first and second blue light emitting diode chips, wherein
color mixture with the yellow light obtained by the wavelength conversion of a part of blue light from the first blue light emitting diode chip by the wavelength conversion layer and the remained part of blue light from the first blue light emitting diode chip results in yellowish white, and
color mixture with the yellow light obtained by the wavelength conversion of a part of blue light from the second blue light emitting diode chip by the wavelength conversion layer and the remained part of blue light from the second blue light emitting diode chip results in bluish white.

13. A linear illuminator, comprising:
a white light emitting diode; and
a light guide member guiding a light incident from the white light emitting diode and linearly illuminating an object to be illuminated, wherein
the white light emitting diode comprises:
first and second blue light emitting diode chips; and
a wavelength conversion layer for wavelength conversion of a part of blue light from the first and second blue light emitting diode chips into yellow light, wherein
color mixture with the yellow light obtained by the wavelength conversion of a part of blue light from the first blue light emitting diode chip by the wavelength conversion layer and the remained part of blue light from the first blue light emitting diode chip results in yellowish white, and
color mixture with the yellow light obtained by the wavelength conversion of a part of blue light from the second blue light emitting diode chip by the wavelength conversion layer and the remained part of blue light from the second blue light emitting diode chip results in bluish white.
